(19) United States
(12) Patent Application Publication
(10) Pub. No.: US 2012/0073653 A1
(43) Pub. Date: Mar. 29, 2012

(54) LIGHT CONCENTRATION ELEMENT ASSEMBLY AND SOLAR CELL APPARATUS HAVING SAME

(75) Inventors: KUO-FENG CHIANG, Chu-Nan (TW); YING-CHIEH LU, Chu-Nan (TW); YU-SHU CHEN, Chu-Nan (TW); ZHENG-JAY HUANG, Chu-Nan (TW); YING-CHING CHEN, Chu-Nan (TW); KUO-MANG LO, Chu-Nan (TW)

(73) Assignee: FOXSEMICON INTEGRATED TECHNOLOGY, INC., Chu-Nan (TW)

(21) Appl. No.: 13/237,909

(22) Filed: Sep. 20, 2011

(30) Foreign Application Priority Data
Sep. 23, 2010 (TW) 099132177

(51) Int. Cl. H01L 31/0232; G02B 17/08

(52) U.S. Cl. 136/259; 359/728

(57) ABSTRACT

A light concentration element assembly includes a Fresnel lens unit and a compound parabolic concentrator. The Fresnel lens unit includes a first Fresnel lens and a second Fresnel lens arranged parallel with each other, and configured for converging light transmitted therethrough. The compound parabolic concentrator includes at least two paraboloidal reflecting surfaces. The parabolic concentrator includes a light incident opening facing the Fresnel lens unit and a light output opening, and the paraboloidal reflecting surfaces are configured for reflecting the converged light from the Fresnel lens unit and outputting the reflected light through the light output opening. A solar cell apparatus using the light concentration element assembly is provided.

### BACKGROUND

1. Technical Field

The present disclosure relates to a light concentration element assembly and a related solar cell apparatus.

2. Description of Related Art

Conventional solar cell apparatuses use reflectors to reflect light to the solar cell, or use convex lenses to converge light to the solar cell. However, the reflectors and convex lenses result in bad light concentration uniformity and bad light concentration efficiency, such that the solar cell cannot be fully excited to work properly.

What is needed, therefore, is a light concentration element assembly and a solar cell apparatus with same, which can overcome the above shortcomings.

### BRIEF DESCRIPTION OF THE DRAWINGS

Many aspects of the light concentration element assembly and solar cell apparatus can be better understood with reference to the following drawings. The components in the drawings are not necessarily drawn to scale, the emphasis instead being placed upon clearly illustrating the principles of the present light concentration element assembly and solar cell apparatus. Moreover, in the drawings, like reference numerals designate corresponding parts throughout the several views.

FIG. 1 is a schematic, cross-sectional view of a solar cell apparatus in accordance with one embodiment, the solar cell apparatus including a light concentration element assembly and a solar cell device.

FIG. 2 is an output flux distribution diagram of the light concentration element assembly of FIG. 1, under a condition that the distance D=122.25 mm.

FIG. 3 is an output flux distribution diagram of the light concentration element assembly of FIG. 1, under a condition that the distance D=110.46 mm.

FIG. 4 is similar to FIG. 2, but showing that the light incident angle is 1 degree.

FIG. 5 is a diagram showing a relationship between the light incident angle and the output efficiency under a condition that the distance D=122.25 mm.

FIG. 6 is similar to FIG. 3, but showing that the light incident angle is 1 degree.

FIG. 7 is a diagram showing a relationship between the light incident angle and the output efficiency under a condition that the distance D=110.46 mm.

### DETAILED DESCRIPTION

Embodiments of the present light concentration element assembly and solar cell apparatus will now be described in detail below and with reference to the drawings.

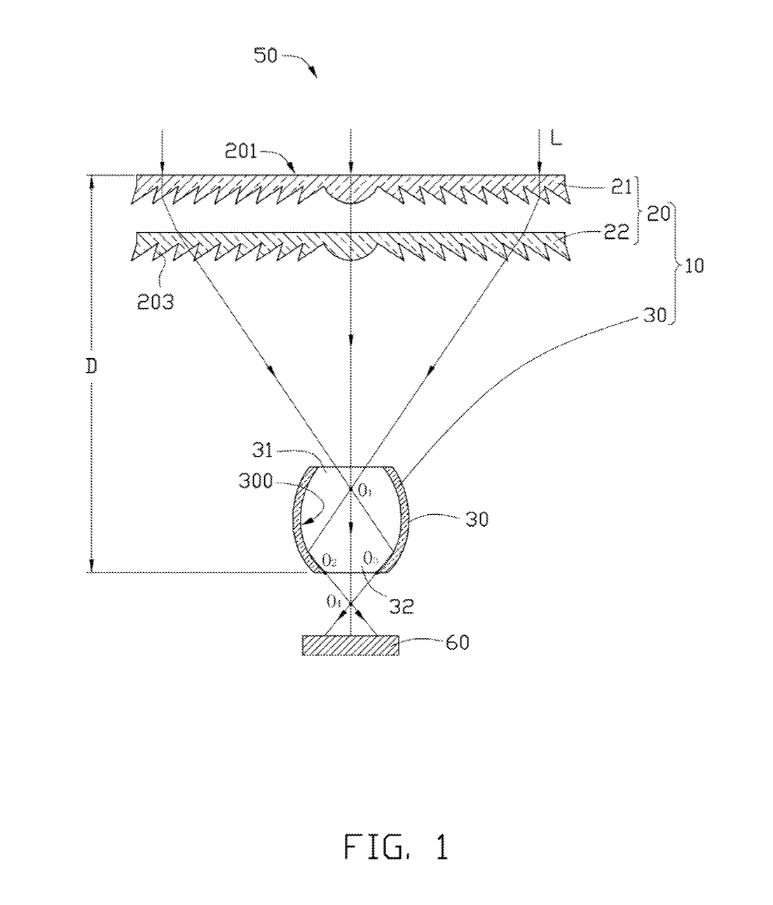

Referring to FIG. 1, a solar cell apparatus 50 includes a light concentration element assembly 10 and a solar cell device 60.

The light concentration element assembly 10 includes a Fresnel lens unit 20 and a compound parabolic concentrator 30.

The Fresnel lens unit 20 includes at least two parallel Fresnel lenses, in the present embodiment, it includes a first Fresnel lens 21 and a second Fresnel lens 22. The first Fresnel lens 21 is arranged above the second Fresnel lens 22, and they are spaced from each other a predetermined distance. In other embodiments, the Fresnel lens unit 20 may include more Fresnel lenses, such as three or four Fresnel lenses. The Fresnel lens unit 20 helps to reduce a focus distance of the entire light concentration element assembly 10, which can make the entire light concentration element assembly 10 smaller in size.

The Fresnel lens unit 20 includes a top surface 201 and a bottom surface 203. The top surface 201 is the top surface of the first Fresnel lens 21, and the bottom surface 203 is the bottom surface of the second Fresnel lens 22. The top surfaces of the first and second Fresnel lenses 21 and 22 are the light incident surfaces, and the bottom surfaces of the first and second Fresnel lenses 21 and 22 are the light output surfaces. An incident light L incident the Fresnel lens unit 20 from the top surface 201, which then passes through the first Fresnel lens 21 and the second Fresnel lens 22 in sequence, and finally outputs from the bottom surface 203. Each of the first Fresnel lens 21 and the second Fresnel lens 22 concentrates the light incident thereon.

The incident surface, i.e., the top surface 201 of the first Fresnel lens 201 is parallel with the incident surface of the second Fresnel lens 22. The output surface of the first Fresnel lens 21 nears the incident surface of the second Fresnel lens 22. In other words, the output surface of the top Fresnel lens faces the incident surface of the bottom Fresnel lens in two adjacent Fresnel lenses.

The bottom surface, i.e., the output surface of each of the Fresnel lenses has a number of grooves formed therein. The grooves oppose to (i.e., faces towards) the inside of the light concentration element assembly 10, which can avoid dust from falling therein. The top surface, i.e., the incident surface of each of the Fresnel lens is a flat surface.

The compound parabolic concentrator 30 follows the Fresnel lens unit 20. The compound parabolic concentrator 30 includes at least two paraboloidal reflecting surfaces 300. The at least two paraboloidal reflecting surfaces 300 oppose each other, and cooperatively form a light incident opening 31 and a light output opening 32 at the respective two ends thereof. The light incident opening 31 opposes the Fresnel lens unit 20, and the light output opening 32 is aligned with the light incident opening 31. The Fresnel lens unit 20 can have a focal point O₁ located inside the compound parabolic concentrator 30, and the light incident the light incident opening 31 can be first focused at the focal point O₁ and then can be spread to the paraboloidal reflecting surfaces 300. Reflection then occurs at the paraboloidal reflecting surfaces 300.

In the present embodiment, the compound parabolic concentrator 30 includes two paraboloidal reflecting surfaces 300, the two paraboloidal reflecting surfaces 300 are symmetrically arranged about a central axis of the compound parabolic concentrator 30. The two paraboloidal reflecting surfaces 300 each have a focal point O₂ and O₃, the focal points O₂ and O₃ of both the paraboloidal reflecting surfaces 300 may be located at the end of the light output opening 32. The light beams through the focal points O₂ and O₃ can directly project on the solar cell device 60. Some light beams may intersect each other, for example, at a point O₄ before reach the solar cell device 60.

The central axis of the compound parabolic concentrator 30 is aligned with that of the Fresnel lens unit 20, thus a highest light output efficiency of the light concentration element assembly 10 can be obtained. Relative to the incident light L, the light is concentrated by the light concentration element assembly 10.

The solar cell device 60 opposes the light output opening 32 to receive the light output from the light concentration element assembly 10. The solar cell device 60 may have one or more solar cells to convert the light energy to electrical energy.

Table 1 shows output data of the light concentration element assembly 10 at situations that a distance D between the top surface 201 of the Fresnel lens unit 20 and the light output opening 32 of the compound parabolic concentrator 30 is changed, but the input flux is the same and the incident light L is perpendicular to the light receiving surface of the Fresnel lens unit 20.

TABLE 1

| Distance | Input | Output | Output | Uniformity |
|---|---|---|---|---|
| (D) | Flux | Flux | Efficiency | (Min/Max) |
| 122.25 mm | 1000 W | 437 W | 43.7% | 2.53% |
| 110.46 mm | 1000 W | 539 W | 53.9% | 6.25% |

Min in Table 1 may represent a minimum output flux on a position of a light receiving surface opposing the light concentration element assembly 10, and Max therein represents at a same time a maximum output flux on another position of the light receiving surface. The light receiving surface may be the surface of the solar cell device 60. It can be concluded from Table 1 that with the same input flux, relative to the 122.25 mm distance D, the output data and the uniformity are better with the 110.46 mm distance D.

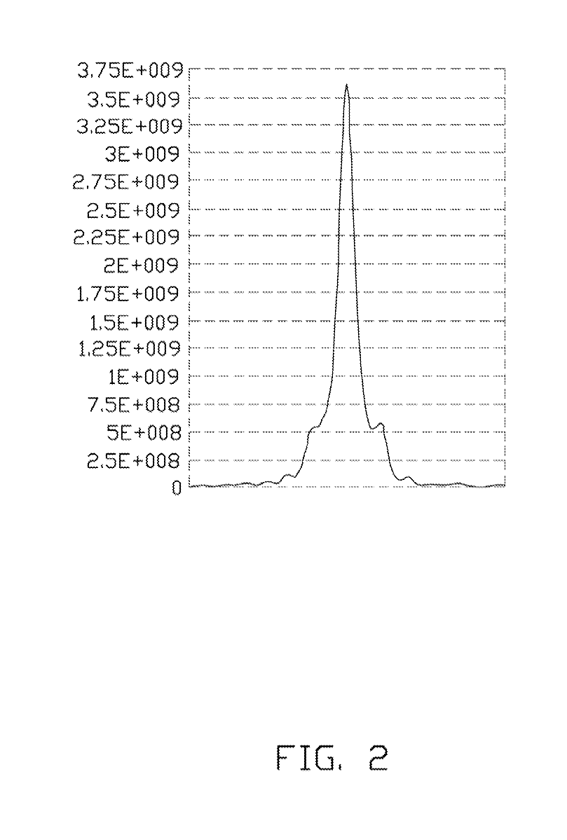

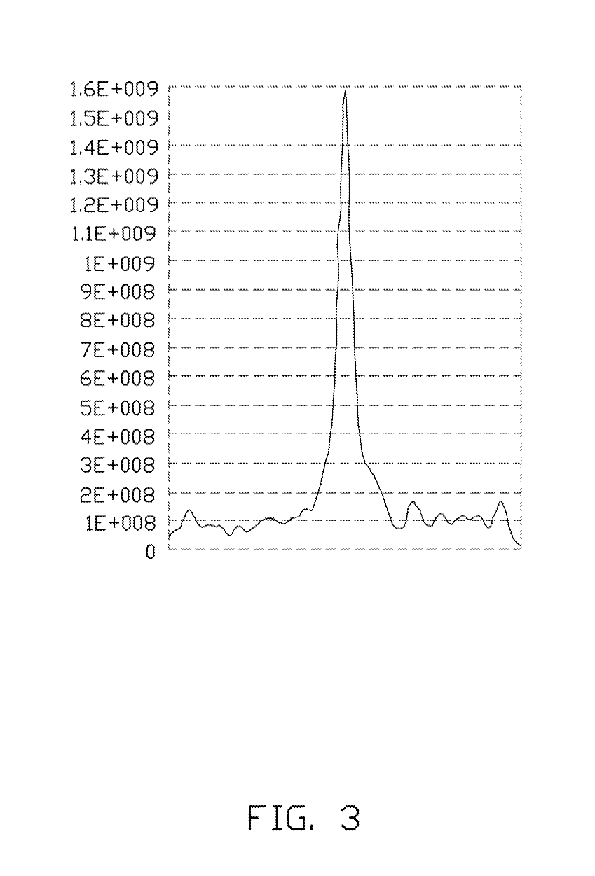

Referring also to FIGS. 2 and 3, FIG. 2 is an output flux distribution along a predetermined line from one end of the light receiving surface to opposite another end of the light receiving surface under the incident light L and the condition of distance D=122.25 mm. FIG. 3 is an output flux distribution along the same predetermined line on the light receiving surface under the incident light L and the condition of distance D=110.46 mm. FIGS. 2 and 3 show that relative to the distance D=122.25 mm, the uniformity is better with the distance D=110.46 mm.

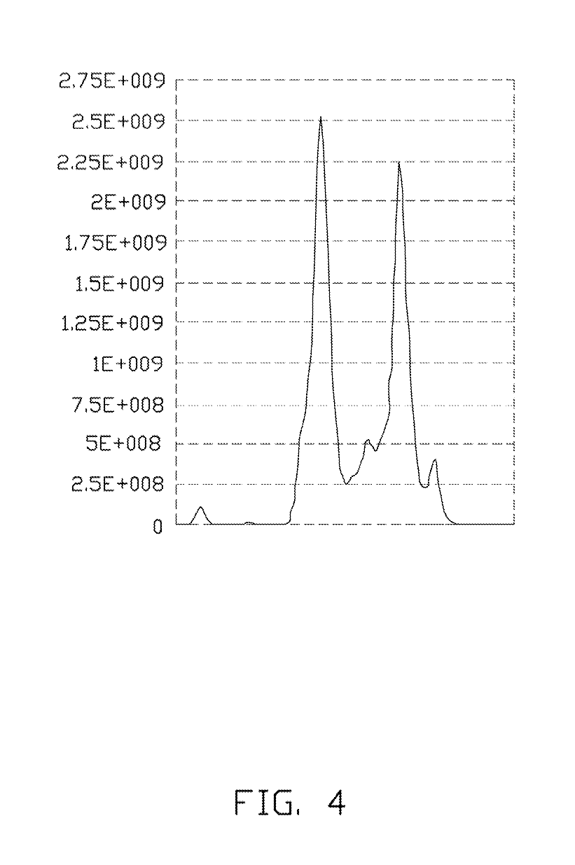

Referring to FIG. 4, FIG. 4 is an output flux distribution of the light concentration element assembly 10 under particular conditions that the distance D=122.25 mm, and a light incident angle is 1 degree. The light incident angle is the angle between the light incident directions and is normal for the light receiving surface (i.e, the light incident surface) of the Fresnel lens unit 20. For a reference, the incident light L shown in FIG. 1 represents the light incident angle is 0 degree. Relative to FIG. 2, FIG. 4 shows that the uniformity is better with the light incident angle is 1 degree.

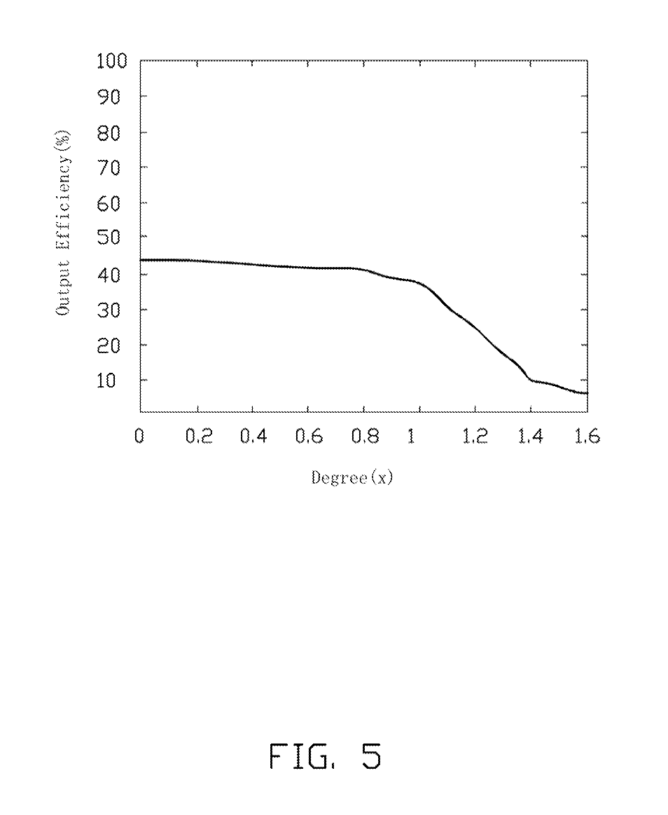

Referring to FIG. 5, shows the relationship between the light incident angle from 0 degree to 1.6 degree and the corresponding output efficiency under the distance D=122.25 mm. It can be concluded from FIG. 5 that the with light incident angle about 1 degree, the output efficiency can be about 36%, and with the light incident angle greater 1 degree and less than 1.6 degree, the output efficiency falls off quickly.

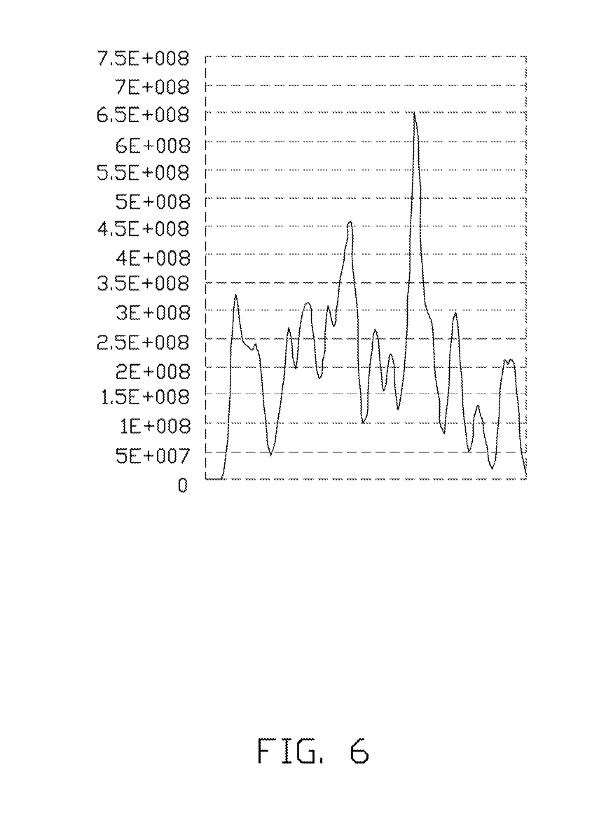

Referring to FIG. 6, is an output flux distribution of the light concentration element assembly 10 under particular conditions that the distance D=110.46 mm, and a light incident angle is 1 degree. Relative to FIG. 3, FIG. 6 shows that the uniformity is better with the light incident angle is 1 degree.

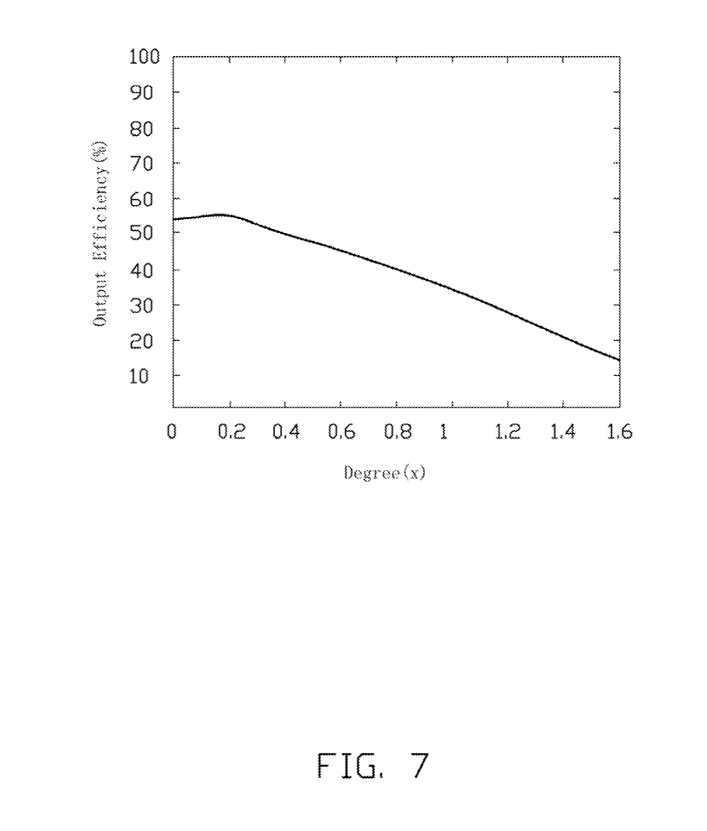

Referring to FIG. 7, shows the relationship between the light incident angle from 0 degree to 1.6 degree and the corresponding output efficiency under the distance D=110.46 mm. It can be concluded from FIG. 5 that the with light incident angle about 1 degree, the output efficiency can be about 35%, and with the light incident angle greater 1 degree and less than 1.6 degree, the output efficiency falls off quickly.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A light concentration element assembly, comprising:
a Fresnel lens unit comprising a first Fresnel lens and a second Fresnel lens arranged parallel with each other, the Fresnel lens unit configured for converging light transmitted therethrough; and
a compound parabolic concentrator comprising two paraboloidal reflecting surfaces, the parabolic concentrator including a light incident opening facing the Fresnel lens unit and a light output opening, the paraboloidal reflecting surfaces configured for reflecting the converged light from the Fresnel lens unit and outputting the reflected light through the light output opening.

2. The light concentration element assembly of claim 1, wherein each of the first and second Fresnel lenses includes a flat surface and a grooved surface, the flat surfaces being light incident surfaces, the grooved surfaces being light output surfaces.

3. The light concentration element assembly of claim 2, wherein the flat surfaces are parallel with each other.

4. The light concentration element assembly of claim 2, wherein a distance between the light incident surface of the first Fresnel lens and the light output opening is in a range from 110.46 mm to 122.25 mm.

5. The light concentration element assembly of claim 1, wherein a central axis of the Fresnel lens unit is aligned with that of the compound parabolic concentrator.

6. The light concentration element assembly of claim 1, wherein the Fresnel lens unit has a focal point located inside the compound parabolic concentrator, and each of the paraboloidal reflecting surfaces has a focal point located at the end of the light output opening.

7. A solar cell apparatus, comprising:
a light concentration element assembly, comprising:
a Fresnel lens unit comprising a first Fresnel lens and a second Fresnel lens arranged parallel with each other, the Fresnel lens unit configured for converging light transmitted therethrough; and
a compound parabolic concentrator comprising two paraboloidal reflecting surfaces, the parabolic concentrator including a light incident opening facing the Fresnel lens unit and a light output opening, the paraboloidal reflecting surfaces configured for reflecting the converged light from the Fresnel lens unit and outputting the reflected light through the light output opening; and
a solar cell device facing the light output opening and configured for receiving and converting the light from the light output opening into electrical energy.

8. The solar cell apparatus of claim 7, wherein each of the first and second Fresnel lenses includes a flat surface and a grooved surface, the flat surfaces being light incident surfaces, the grooved surfaces being light output surfaces.

9. The solar cell apparatus of claim 8, wherein the flat surfaces are parallel with each other.

10. The solar cell apparatus of claim 8, wherein a distance between the light incident surface of the first Fresnel lens and the light output opening is in a range from 110.46 mm to 122.25 mm.

11. The solar cell apparatus of claim 7, wherein a central axis of the Fresnel lens unit is aligned with that of the compound parabolic concentrator.

12. The solar cell apparatus of claim 7, wherein the Fresnel lens unit has a focal point located inside the compound parabolic concentrator, and each of the paraboloidal reflecting surfaces has a focal point located at the end of the light output opening.
